(19) United States
(12) Patent Application Publication
(10) Pub. No.: US 2009/0121777 A1
(43) Pub. Date: May 14, 2009

(54) SEMICONDUCTOR DEVICE, SEMICONDUCTOR DEVICE MANUFACTURING METHOD, POWER CONTROL DEVICE, AND ELECTRONIC EQUIPMENT AND MODULE

(76) Inventor: Satoshi NAKAJIMA, Katsuragi-shi (JP)

Correspondence Address: BIRCH STEWART KOLASCH & BIRCH, PO BOX 747, FALLS CHURCH, VA, 22040-0747, US

(21) Appl. No.: 12/257,502

(22) Filed: Oct. 24, 2008

(30) Foreign Application Priority Data
Nov. 13, 2007 (JP) 2007-294087

(51) Int. Cl. H03K 17/74

(52) U.S. Cl. 327/493

(57) ABSTRACT

A semiconductor device of the invention for miniaturizing and cost reduction includes: a solid-state relay 30 having a first light emitting element 10, a light triggered element 16 for receiving light from the first light emitting element 10, and translucent resin 23 for sealing the first light emitting element 10 and the light triggered element 16; a bidirectional input-type photocoupler 31 having second, third light emitting elements 12, 14 of antiparallel connection, a phototransistor 19 for receiving light from the second, third light emitting elements, and translucent resin 23 for sealing the second, third light emitting elements and the phototransistor 19; and a light shielding wall 25 for light-shielding the solid-state relay 30 and the bidirectional input-type photocoupler 31 from each other. The solid-state relay 30 and the bidirectional input-type photocoupler 31 are integrated into one package in a light-shielded state from each other by the light shielding wall 25.

### CROSS-REFERENCE TO RELATED APPLICATIONS

This nonprovisional application claims priority under 35 U.S.C. §119(a) on Patent Application No(s). 2007-294087 filed in Japan on Nov. 13, 2007, the entire contents of which are hereby incorporated by reference.

### BACKGROUND OF THE INVENTION

The present invention relates to a semiconductor device, a semiconductor device manufacturing method, a power control device, and electronic equipment and module. More specifically, the invention relates to a semiconductor device for controlling AC power fed to a load such as an illuminating device, and a manufacturing method for the semiconductor device, as well as to a power control device, electronic equipment and a module using the semiconductor device.

Conventionally, there has been provided a semiconductor device to be used in power control devices for driving LED illumination. This semiconductor device generally requires a DC (Direct Current) power supply, so that when electric power is supplied from an AC (Alternating Current) power supply, the semiconductor device requires an AC-to-DC converter.

Meanwhile, there has also been provided a semiconductor device in which, for power conditioning on an AC direct-drivable load, a non-zero-cross type light triggered element is used for phase control of an AC input voltage inputted to the load, and in which a bidirectional photocoupler is used to detect a zero-cross point (a point at which the AC voltage crosses the GND) of the AC input voltage.

Also, as a power control device for zero-cross detection of an AC voltage, there has been a power control device in which an input-side light emitting element emits light at a timing of switching from positive to negative side or from negative to positive side of the AC input voltage and a phototransistor, receiving the light from the light emitting element, outputs an output signal to detect the zero-cross point (see, e.g., JP H10-145200 A).

Further, as another conventional power control device, there has been provided a dimmer which uses a phase control method implemented by using a solid-state relay (see, e.g., JP 2001-126882 A).

As driver-use semiconductor devices to be included in electrical appliances such as illuminating devices (e.g., bulb-type illuminating devices), a device using an AC-to-DC converter would be increased in size as a problem. As a result, there is a need for a small-size semiconductor device which is so sized as to be accommodated in the base of a light bulb or the like and which can be driven directly with AC.

Further, the conventional photocoupler for zero-cross detection of AC voltage and the solid-state relay to be used for phase control are manufactured independently of each other as semiconductor devices having different functions, and mounted on the circuit board. As a result, there are problems of increased mounting area and increased manufacturing cost.

### SUMMARY OF THE INVENTION

Accordingly, an object of the present invention is to provide a semiconductor device which allows size reduction and manufacturing cost reduction to be achieved, as well as a manufacturing method for the semiconductor device.

Another object of the invention is to provide a power control device using a semiconductor device which allows size reduction and manufacturing cost reduction to be achieved, as well as electronic equipment using the semiconductor device and a module using the semiconductor device.

In order to achieve the above object, there is provided a semiconductor device for use in power control devices for controlling AC power fed from an AC power supply to a load, comprising:

a solid-state relay having: a first light emitting element to which a control signal for control of the AC power is inputted; a light triggered element for, upon reception of light from the first light emitting element, turning on and off an AC voltage applied from the AC power supply to the load; and a first resin sealing portion for sealing the first light emitting element and the light triggered element with translucent resin;

a bidirectional input-type photocoupler having: second, third light emitting elements which are connected in parallel in mutually opposite directions and to which a signal representing the AC voltage is inputted; a phototransistor for, upon reception of light from the second, third light emitting elements, outputting a signal representing a zero cross of the AC voltage; and a second resin sealing portion for sealing the second, third light emitting elements and the phototransistor with translucent resin; and

a light shielding wall for light-shielding the solid-state relay and the bidirectional input-type photocoupler from each other, wherein

in a state that the solid-state relay and the bidirectional input-type photocoupler are light-shielded from each other by the light shielding wall, the solid-state relay and the bidirectional input-type photocoupler are integrated into one package.

According to the above semiconductor device, in the power control device for controlling AC power fed from the AC power supply to a load, based on a signal representing a zero cross of an AC voltage outputted from the phototransistor of the bidirectional input-type photocoupler to which a signal representing the AC voltage is inputted on its input side, a control signal is inputted to the first light emitting element of the solid-state relay integrated into one package together with the bidirectional input-type photocoupler, so that the AC voltage fed from the AC power supply to the load is turned on and off by the light triggered element of the solid-state relay. Since the solid-state relay and the bidirectional input-type photocoupler are integrated into one package in a light-shielded state from each other by the light shielding wall, light derived from each of the two light emitting elements has no effect on the other light emitting element. Thus, the semiconductor device suitable for the power control device that controls the AC power fed from the AC power supply to the load can be reduced in mounting area as well as in manufacturing cost.

In one embodiment of the invention, the first, second, third light emitting elements are placed at connecting portions of a plurality of leads in which the connecting portions are arrayed along one identical plane.

According to the embodiment, since the first, second, third light emitting elements are placed at connecting portions of a plurality of leads in which the connecting portions are arrayed along one identical plane, one die-bond device and the like can be shared thereamong during the mounting of the first, second, third light emitting elements onto the leads, by which the manufacturing cost can be reduced. Conversely, in the case where the first, second, third light emitting elements are not placed on one identical plane, two to three die-bond devices and the like for the mounting of the light emitting elements onto the lead frame are necessitated, resulting in lower efficiency.

In one embodiment of the invention, the light triggered element and the phototransistor are fixed to the connecting portions of the leads with high heat conductivity paste or solder, and

the light triggered element and the phototransistor are electrically insulated from each other.

According to the embodiment, the light triggered element and the phototransistor, which are fixed to the connecting portions of the leads with high heat conductivity paste or solder, are electrically insulated from each other, making it easier to achieve insulation of the primary-side circuit including the AC power supply and the secondary-side control-related circuit from each other.

In one embodiment of the invention, the semiconductor device further comprises a temperature sensor which is placed in the one identical package of the solid-state relay and the bidirectional input-type photocoupler, and which is fixed to the connecting portions of the leads with high heat conductivity paste or solder.

According to the embodiment, by the placement that the temperature sensor fixed to a connecting portion of the lead with high heat conductivity paste or solder within one identical package of the solid-state relay and the bidirectional input-type photocoupler, temperature of the lead can be monitored accurately. Also, by connecting a load to the lead to which the temperature sensor is fixed outside the package, it also becomes possible to detect the temperature of the load via the lead.

In one embodiment of the invention, the temperature sensor detects a junction temperature of the light triggered element or a package temperature.

According to the embodiment, based on the junction temperature of the light triggered element or the package temperature detected by the temperature sensor, power conditioning on the load can be fulfilled so that temperature increases of the light triggered element or temperature increases of the package are suppressed in the power control device having the control section such as a microcomputer.

In one embodiment of the invention, the temperature sensor and the light triggered element are placed on one lead, and

the lead on which the temperature sensor and the light triggered element are placed is led outside.

According to the embodiment, by leading out the lead in which the temperature sensor and the light triggered element are placed, or by attaching a heat sink plate formed of metal, ceramic or the like at the led-out lead portion, the temperature of the load connected to the lead via the heat sink plate outside can be sensed more accurately.

In one embodiment of the invention, the temperature sensor and the light triggered element are placed on one lead, the semiconductor device further comprising

a heat sink plate which is attached to the lead on which the temperature sensor and the light triggered element are placed.

According to the embodiment, by attaching a heat sink plate to one identical lead in which the temperature sensor and the light triggered element are placed, the heat conductivity is raised so that the temperature of the light triggered element can be sensed more accurately.

In one embodiment of the invention, the temperature sensor is a thermistor.

According to the embodiment, by using a thermistor for the temperature sensor, the temperature sensor can be placed in a small space within the package, allowing a miniaturization of the device to be achieved.

In one embodiment of the invention, the light triggered element is a photothyristor or a bidirectional photothyristor, or has a structure that a gate of a triac is connected to an output terminal of a photothyristor or a bidirectional photothyristor.

In one embodiment of the invention, the light triggered element is a photothyristor or bidirectional photothyristor having a zero-cross function.

According to the embodiment, by using a photothyristor or bidirectional photothyristor having a zero-cross function as the light triggered element, it becomes possible to perform the on/off control more easily, so that the noise withstanding level can be increased as compared with non-zero-cross cases.

There is also provided a method for manufacturing a semiconductor device for use in power control devices for controlling AC power fed from an AC power supply to a load, the semiconductor device comprising:

a solid-state relay having: a first light emitting element to which a control signal for control of the AC power is inputted; a light triggered element for, upon reception of light from the first light emitting element, turning on and off an AC voltage applied from the AC power supply to the load; and a first resin sealing portion for sealing the first light emitting element and the light triggered element with translucent resin;

a bidirectional input-type photocoupler having: second, third light emitting elements which are connected in parallel in mutually opposite directions and to which a signal representing the AC voltage is inputted; a phototransistor for, upon reception of light from the second, third light emitting elements, outputting a signal representing a zero cross of the AC voltage; and a second resin sealing portion for sealing the second, third light emitting elements and the phototransistor with translucent resin;

a light shielding wall for light-shielding the solid-state relay and the bidirectional input-type photocoupler from each other, and

a temperature sensor which is placed in one identical package of the solid-state relay and the bidirectional input-type photocoupler, and which is fixed to connecting portions of the leads with high heat conductivity paste or solder, wherein

in a state that the solid-state relay and the bidirectional input-type photocoupler are light-shielded from each other by the light shielding wall, the solid-state relay and the bidirectional input-type photocoupler are integrated into one package, the manufacturing method comprising the steps of:

applying insulative resin to regions on one lead at which the light triggered element and the temperature sensor are to be mounted, and

after the application of the insulative resin, mounting the light triggered element and the temperature sensor onto the one lead via the insulative resin.

According to the above method, by mounting the light triggered element and the temperature sensor on one identical lead via insulative resin, the temperature of the light triggered element can be easily detected while the light triggered element and the temperature sensor are electrically insulated from each other.

In one embodiment of the invention, there is provided a power control device comprising:

the above semiconductor device;

a control section for, based on a signal representing a zero cross of the AC voltage outputted from the phototransistor of the bidirectional input-type photocoupler of the semiconductor device, outputting the control signal to the first light emitting element of the solid-state relay to turn on and off the light triggered element of the solid-state relay so that AC power fed from the AC power supply to the load is controlled, wherein

the control section performs overheat protection control for the semiconductor device based on a temperature detected by the temperature sensor of the semiconductor device.

According to the embodiment, based on a signal representing a zero cross of an AC voltage outputted from the phototransistor of the bidirectional input-type photocoupler of the semiconductor device, the control section outputs a control signal to the first light emitting element of the solid-state relay to turn on and off the AC voltage fed from the AC power supply to the load by the light triggered element of the solid-state relay. During this operation, overheat protection control for the semiconductor device is performed based on the temperature detected by the temperature sensor of the semiconductor device, by which the semiconductor device can be prevented from damage due to heat. Also, in the case of an LED illumination load, performing the overheat protection control makes it possible to suppress shortening of LED life due to temperature.

In one embodiment of the invention, there is provided an electronic equipment in which the above semiconductor device is mounted.

According to the embodiment, by mounting the semiconductor device thereon, it becomes possible to effectively utilize the mounting space, allowing a miniaturization of the electronic equipment to be achieved.

In one embodiment of the invention, there is provided a module in which the above semiconductor device or the above power control device or the above electronic equipment and an LED light source as the load are integrated together.

According to the embodiment, by making up a module in which the semiconductor device or power control device and an LED light source are integrated together, a miniaturization as an illuminating device can be achieved. Also, by integration with the power control device, it becomes also possible to perform the overheat protection control on the LED light source that involves large amounts of heat generation in its use.

As apparent from the above description, according to the semiconductor device of the invention, there can be realized a semiconductor device, a semiconductor device manufacturing method, a power control device, and electronic equipment and module that allow a miniaturization of each device as well as its manufacturing cost to be reduced.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is an equivalent circuit diagram of a power control device using a semiconductor device according to a first embodiment of the invention;

FIG. 2 is a structural view of the first embodiment of the semiconductor device of the invention;

FIG. 3 is a plan view showing an outline of the semiconductor device;

FIG. 4 is an equivalent circuit diagram of the semiconductor device;

FIG. 5 is an equivalent circuit diagram of a power control device using a semiconductor device according to a second and third embodiment of the invention;

FIG. 6 is a structural view of the second embodiment of the semiconductor device of the invention;

FIG. 7 is a plan view showing an outline of the semiconductor device;

FIG. 8 is an equivalent circuit diagram of the semiconductor device;

FIG. 9 is a structural view of the third embodiment of the semiconductor device of the invention;

FIG. 10 is a schematic view showing a secondary-side structure of the semiconductor device;

FIG. 11 is a structural view of an integrated module of the semiconductor device and an LED light source;

FIG. 12 is a structural view of an integrated module of the semiconductor device and an LED light source;

FIG. 13 is a structural view of a modification of the semiconductor device;

FIG. 14 is a flowchart of manufacturing process for a semiconductor device according to a fourth embodiment of the invention; and

FIG. 15 is a plan view of the semiconductor device before its insulation cutting.

### DETAILED DESCRIPTION OF THE INVENTION

Hereinbelow, a semiconductor device, a semiconductor device manufacturing method, a power control device, and electronic equipment and module according to the present invention will be described in detail by way of embodiments thereof illustrated in the accompanying drawings.

### First Embodiment

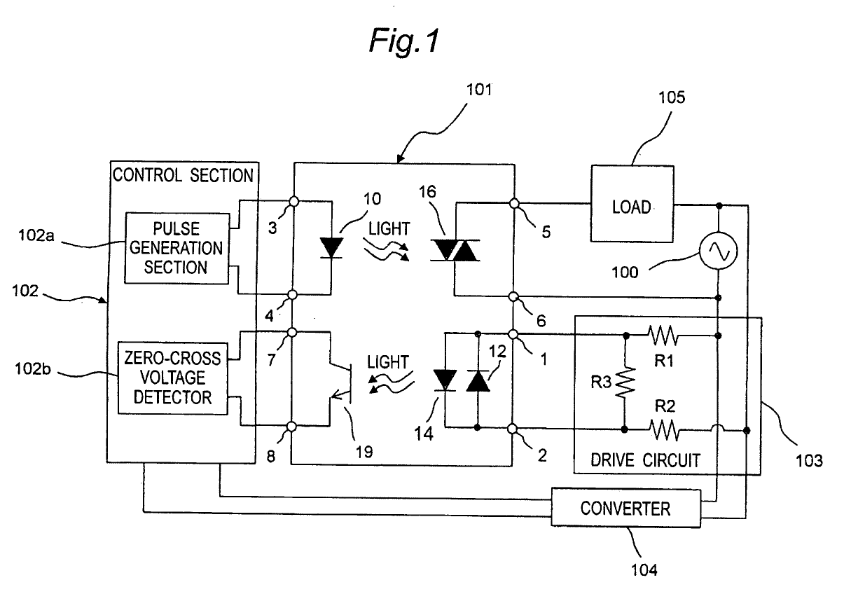

FIG. 1 shows an equivalent circuit diagram of a power control device using a semiconductor device according to a first embodiment of the invention. The power control device of this first embodiment includes a semiconductor device 101, a control section 102 connected to the secondary side of the semiconductor device 101, a drive circuit 103 to which an AC voltage derived from an AC power supply 100 is inputted and which outputs a signal representing an AC voltage to the semiconductor device 101, and a converter 104 which converts an AC voltage fed from the drive circuit 103 into a DC voltage and feeds the DC voltage to the control section 102. One end of a load 105 is connected to one end of a light triggered element 16 of the semiconductor device 101, one end of the AC power supply 100 is connected to the other end of the load 105, and the other end of the light triggered element 16 of the semiconductor device 101 is connected to the other end of the AC power supply 100.

The control section 102 is composed of a microcomputer, input/output circuits and the like, and moreover has a pulse generation section 102a and a zero-cross voltage detection section 102b.

The drive circuit 103 has a resistor R1 one end of which is connected to one end of the AC power supply 100 and the other end of which is connected to a first lead 1 of the semiconductor device 101, a resistor R2 one end of which is connected to the other end of the AC power supply 100 and the other end of which is connected to a second lead 2 of the semiconductor device 101, and a resistor R3 connected between the other end of the resistor R1 and the other end of the resistor R2. Currents to be inputted to second, third light emitting elements 12, 14 of the semiconductor device 101 are limited by the drive circuit 103. It is noted that the drive circuit 103 may also be implemented by other circuit construction without being limited to the resistor circuit shown in FIG. 1.

Phase control with the use of the power control device of the first embodiment is described below. Of the antiparallel-arranged second, third light emitting elements 12, 14 connected to the first, second leads 1, 2, one light emitting element emits light when an AC input signal (representing an AC voltage of the AC power supply 100) derived from the drive circuit 103 has changed from negative to positive direction, and the other light emitting element emits light when the AC input signal has changed from positive to negative direction. A phototransistor 19 that has received light from the second, third light emitting elements 12, 14 transmits a signal representing a zero cross of the AC voltage to the zero-cross voltage detection section 102b via seventh, eighth leads 7, 8. A signal derived from the zero-cross voltage detection section 102b serves as a reference point for the zero-cross point of the AC voltage, and this information is transmitted to the pulse generation section 102a. Thereafter, the pulse generation section 102a generates a pulse for triggering the light triggered element 16 at an arbitrary timing from the zero-cross reference point. The timing and pulse width are controlled by the microcomputer of the control section 102.

The power supply for the control section 102, as shown in FIG. 1, is so formed that an AC voltage fed from the drive circuit 103 is converted into a DC voltage by the converter 104 and supplied as such. It is noted that a DC battery may also be provided alternatively as the power supply for the control section 102.

A pulse from the pulse generation section 102a is transmitted to a first light emitting element 10 connected thereto via third, fourth leads 3, 4, and the first light emitting element 10 emits light in response to the pulse, so that the light triggered element 16, upon reception of the light, is turned ON. The light triggered element 16, once having come to an ON state, keeps turned ON until the AC voltage of the AC power supply 100 comes to a nearly zero-cross point. Because of this, the load 105 connected to the light triggered element 16 via a sixth lead 6 keeps energized while the light triggered element 16 keeps turned ON. The load 105 phase-controlled in this way is energized by illuminating devices with fluorescent lamps or light emitting diodes or other devices.

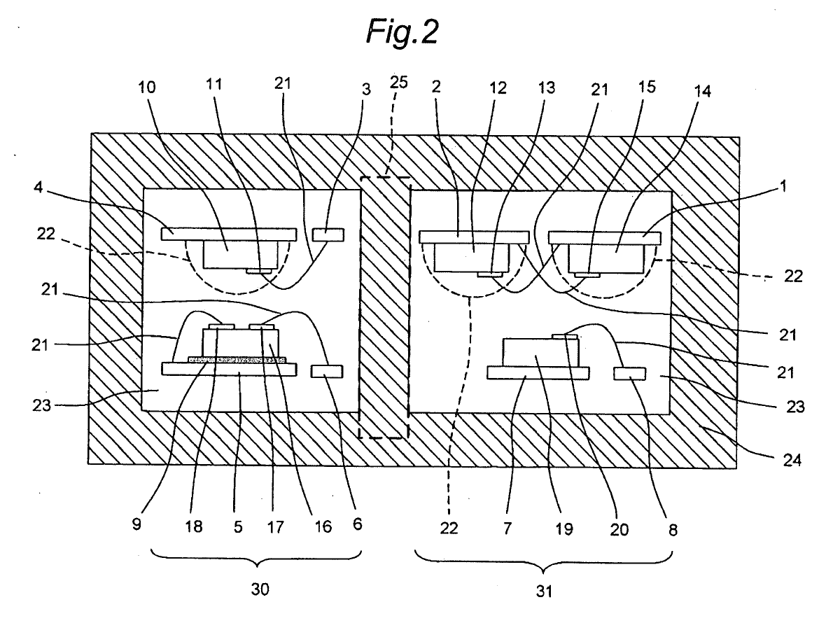

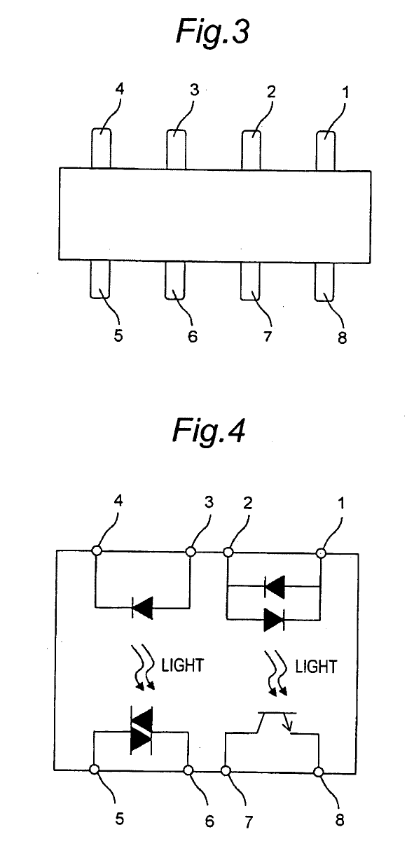

FIG. 2 shows a structural view of the semiconductor device. Also, FIG. 3 is a plan view showing an outline of the semiconductor device and FIG. 4 is an equivalent circuit diagram of the semiconductor device.

As shown in FIG. 2, the semiconductor device 101 has a solid-state relay 30 and a bidirectional input-type photocoupler 31.

The solid-state relay 30 has a first light emitting element 10 die-bonded to a connecting portion of the metallic fourth lead 4 with conductive paste or the like, and a light triggered element 16 die-bonded onto insulative resin 9 on a connecting portion of a metallic fifth lead 5. The first light emitting element 10 and the light triggered element 16 are so placed as to face each other so that light emitted from the first light emitting element 10 is received by the light triggered element 16. The first light emitting element 10 is sealed with precoat resin 22. The metallic third lead 3 is electrically connected to an anode electrode 11 of the first light emitting element 10 with a wire 21, and the fourth lead 4 is electrically connected to a cathode electrode of the first light emitting element 10. Also, the fifth lead 5 is electrically connected to a cathode (anode) electrode 18 of the light triggered element 16 with the wire 21, and the sixth lead 6 is electrically connected to an anode (cathode) electrode 17 of the light triggered element 16 with the wire 21. The solid-state relay 30 is filled with translucent resin 23 as an example of the first resin sealing portion.

On the other hand, the bidirectional input-type photocoupler 31 has a third light emitting element 14 die-bonded to a connecting portion of the first lead 1 with conductive paste or the like, a second light emitting element 12 die-bonded to a connecting portion of the second lead 2 with conductive paste or the like, and a phototransistor 19 die-bonded to a connecting portion of the seventh lead 7 with conductive paste or the like. Light emitting surfaces of the second, third light emitting elements 12, 14 are so positioned as to face toward the same direction, and the phototransistor 19 is so positioned as to receive light derived from the second, third light emitting elements 12, 14. In addition, the first lead 1 is electrically connected to a cathode electrode of the third light emitting element 14, and moreover electrically connected also to an anode electrode 13 of the second light emitting element with the wire 21. Further, the second lead 2 is electrically connected to a cathode electrode of the second light emitting element 12, and moreover electrically connected also to an anode electrode 15 of the third light emitting element with the wire 21. A collector electrode of the phototransistor 19 is electrically connected to the seventh lead 7, and the eighth lead 8 is electrically connected to an emitter electrode 20 of the phototransistor 19 with the wire 21. The bidirectional input-type photocoupler 31 is filled with translucent resin 23 as an example of the second resin sealing portion.

The solid-state relay 30 and the bidirectional input-type photocoupler 31 are covered with light shielding resin 24 so as to be integrated together. These integrated solid-state relay 30 and bidirectional input-type photocoupler 31 are so structured as to be prevented by a light shielding wall 25 to each other from accepting light derived from the first light emitting element 10 and the third light emitting element 14 or the second light emitting element 12.

Also, the light triggered element 16 and the phototransistor 19 are of a structure fixed with high heat conductivity paste or solder and mutually electrically-insulated.

With the use of the semiconductor device of this first embodiment, the mounting space in the power control device can be reduced and moreover the manufacturing cost can be suppressed low.

In manufacture of this semiconductor device, in which the first to fourth leads 1-4 are on the same side as shown in FIGS. 2 and 3, if the first to third light emitting elements are electrically connected to any one of the first to fourth leads 1-4, one manufacturing device for the precoat resin 22 will do, so that the cost necessary for the manufacture can be cut down. In addition, although the first to third light emitting elements 10, 12, 14 are die-bonded on the same side in FIGS. 2 and 3, yet it is also possible that, for example, the positions of the second light emitting element 12 and the third light emitting element 14 and the position of the phototransistor 19 are replaced with each other.

According to the semiconductor device 101 constructed as described above, in the power control device for controlling AC power fed from the AC power supply 100 to a load 105, a signal representing the AC voltage is inputted to the second, third light emitting elements 12, 14 of the bidirectional input-type photocoupler 31 and the phototransistor 19 of the photocoupler 31 outputs a signal representing a zero cross of the AC voltage and based on the signal a control signal is inputted to the first light emitting element 10 on the input side of the solid-state relay 30. Then, the light triggered element 16 on the output side of the solid-state relay 30 controls the AC voltage fed from the AC power supply 100 to the load 105. Since the solid-state relay 30 and the bidirectional input-type photocoupler 31 are integrated into one package in a light-shielded state from each other by the light shielding wall 25, light derived from each of the two light emitting elements has no effect on the other light emitting element. Thus, the semiconductor device 101 suitable for the power control device that controls the AC power fed from the AC power supply 100 to the load can be provided in small size while its manufacturing cost can be reduced.

Further miniaturization becomes implementable for the semiconductor device to be used in the power control device of AC direct drive method such as LED illuminating devices. Thus, the semiconductor device can be accommodated in a narrow space of, for example, the base of a bulb-type illuminating device or the like, and moreover assembling time and labor can be reduced by virtue of its manufacturability by one assembly process.

Further, by the placement that the first, second, third light emitting elements 10, 12, 14 are placed at connecting portions of the first to fourth leads 1-4 having those connecting portions arrayed along one identical plane, one die-bond device and the like can be shared thereamong, by which the manufacturing cost can be reduced. Conversely, in the case where the first, second, third light emitting elements 10, 12, 14 are not placed on one identical plane, two to three die-bond devices and the like for the mounting of the light emitting elements onto the lead frame are necessitated, resulting in lower efficiency.

Furthermore, the light triggered element 16 and the phototransistor 19, which are fixed to connecting portions of the fifth to eighth leads 5-8 with high heat conductivity paste or solder, are electrically insulated from each other, making it easier to achieve insulation of the primary-side circuit including the AC power supply 100 and the secondary-side circuit including the control section 102 from each other.

### Second Embodiment

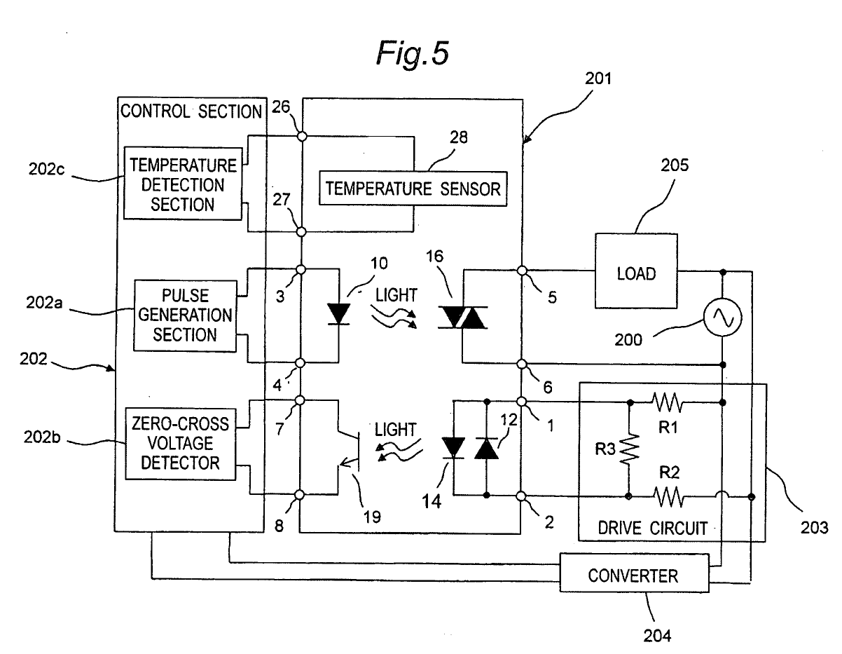

FIG. 5 shows an equivalent circuit diagram of a power control device using the semiconductor device according to the second embodiment of the invention. The power control device of the second embodiment includes a semiconductor device 201, a control section 202 connected to the secondary side of the semiconductor device 201, a drive circuit 203 to which an AC voltage derived from an AC power supply 200 is inputted and which outputs a signal representing an AC voltage to the semiconductor device 201, and a converter 204 which converts an AC voltage fed from the drive circuit 203 into a DC voltage and feeds the DC voltage to the control section 202. One end of a load 205 is connected to one end of a light triggered element 16 of the semiconductor device 201, one end of the AC power supply 200 is connected to the other end of the load 205, and the other end of the light triggered element 16 of the semiconductor device 201 is connected to the other end of the AC power supply 200.

The control section 202 is composed of a microcomputer, input/output circuits and the like, and moreover has a pulse generation section 202a, a zero-cross voltage detection section 202b, and a temperature detection section 202c.

The drive circuit 203 is similar in construction to the drive circuit 103 of the first embodiment shown in FIG. 1.

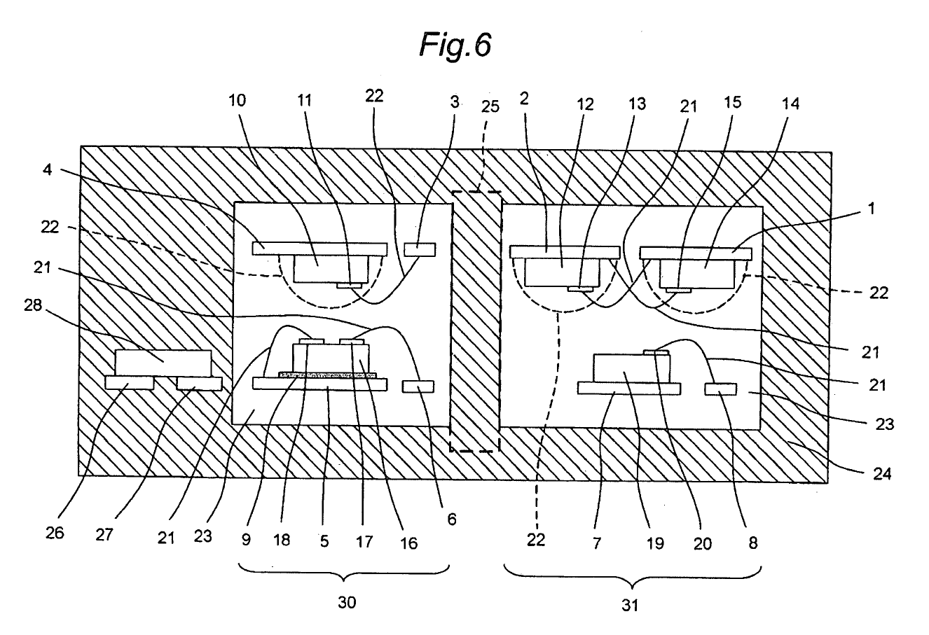

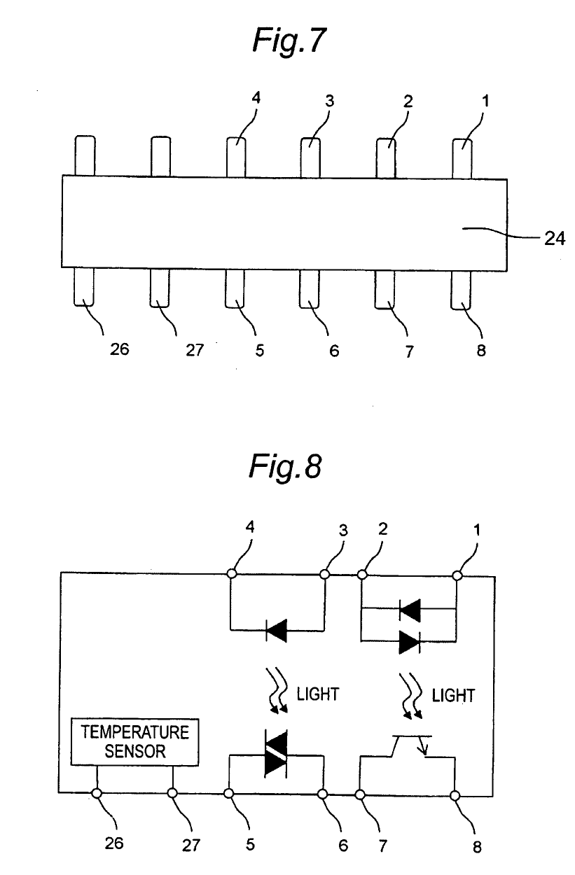

FIG. 6 shows a structural view of the semiconductor device 201. FIG. 7 is a plan view showing an outline of the semiconductor device 201, and FIG. 8 is an equivalent circuit diagram of the semiconductor device 201. The semiconductor device 201 of this second embodiment is similar in construction to the semiconductor device 101 of the first embodiment except a temperature sensor 28, and therefore like component members are designated by like reference numerals.

In the semiconductor device 201 of this second embodiment, the temperature sensor 28 is electrically insulated from the solid-state relay 30 and the bidirectional input-type photocoupler 31. Also, two terminals of the temperature sensor 28 are fixed to connecting portions of a ninth lead 26 and a tenth lead 27 with high heat conductivity paste or solder.

As shown in FIG. 5, upon reception of a signal from the temperature sensor 28, the temperature detection section 202c detects a package temperature of the semiconductor device 201. The control section 202 applies feedback control based on the package temperature to the pulse generation section 202a so as to correct temperature characteristics of the solid-state relay 30, as a result a stable AC power can be fed to the load 205. Also, in the case of a module which is so structured that the load 205 and the semiconductor device 201 are integrated together for compactness, overheat protection control can be fulfilled by estimating the temperature of the load 205 from the package temperature.

Also, the temperature sensor 28 senses a junction temperature of the light triggered element 16 or a package temperature, and the control section 202 adjusts power supply to the load 205 based on the sensed temperature so as to suppress temperature increases of the light triggered element 16 or the package.

Also, in the power control device of this second embodiment, the control section 202 outputs a control signal to the first light emitting element 10 of the solid-state relay 30 based on a signal representing a zero cross of an AC voltage derived from the phototransistor 19 of the bidirectional input-type photocoupler 31 of the semiconductor device 201. The light triggered element 16 of the solid-state relay 30, upon receiving the light emitted from the first light emitting element 10, turns on or off the AC voltage supply from the AC power supply 200 to the load 205, so that overheat protection control for the semiconductor device 201 is performed based on the temperature sensed by the temperature sensor 28 of the semiconductor device 201, as a result the semiconductor device 201 can be prevented from damage due to heat.

In the power control device of the second embodiment, when the load is LED illumination for example, decreases of LED life due to temperature can be suppressed by the overheat protection control.

### Third Embodiment

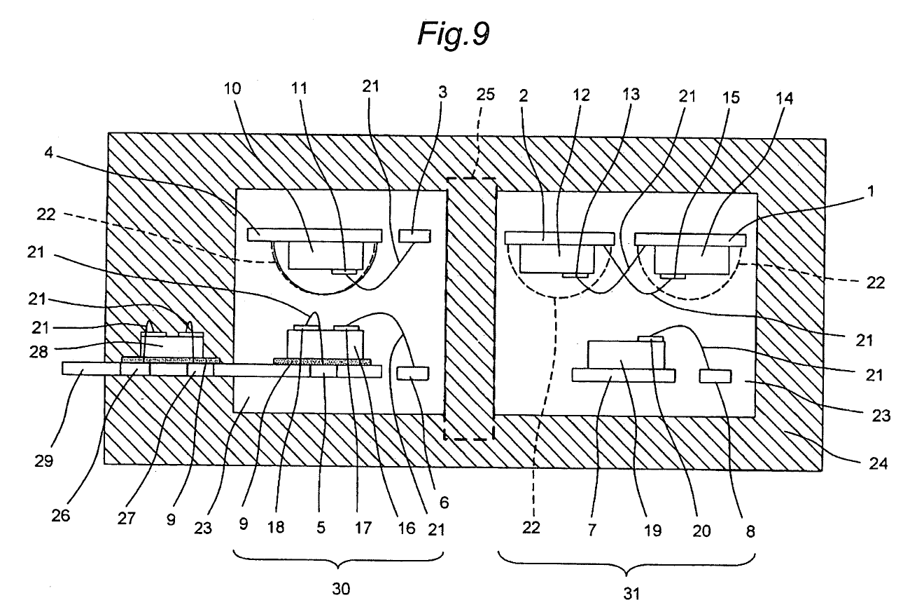

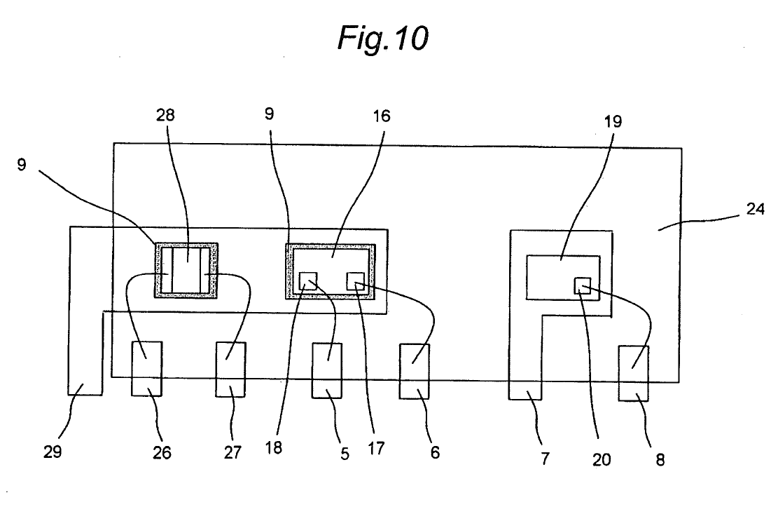

FIG. 9 shows a structural view of a semiconductor device according to a third embodiment of the invention. FIG. 10 shows a schematic view showing a secondary-side structure of the semiconductor device. The semiconductor device of this third embodiment is similar in construction to the semiconductor device of the second embodiment except an eleventh lead 29, and therefore like component members are designated by like reference numerals.

In the semiconductor device of the third embodiment, as shown in FIG. 9, the light triggered element 16 and the temperature sensor 28 are of a structure that insulative resin 9 is placed on one identical eleventh lead 29, followed by die bonding.

The eleventh lead 29 is so structured that its one end is led outside from a secondary mold portion formed of light shielding resin 24 as an example of the resin sealing portion.

A junction temperature of the light triggered element 16 or a package temperature can be sensed by the temperature sensor 28. For this purpose, the insulative resin 9 is preferably of better heat conductivity because it is enabled to achieve a more accurate temperature sensing.

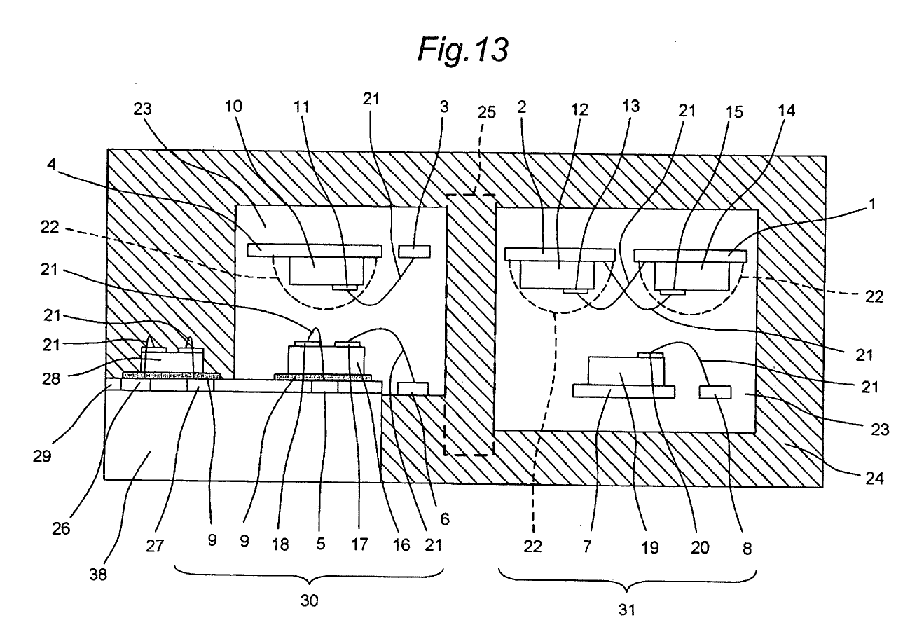

Further, with a structure that a heat sink plate 38 formed of metal, ceramic or the like is attached to the eleventh lead 29 as shown in a modification of FIG. 13, the heat conductivity is raised so that an even more accurate temperature sensing can be achieved.

The semiconductor device of the third embodiment has effects similar to those of the semiconductor device of the first embodiment.

The light triggered element 16 in the first to third embodiments shown above may be a photothyristor or a bidirectional photothyristor. The light triggered element 16 otherwise may be one in which the gate of a triac is connected to an output terminal of a photothyristor or a bidirectional photothyristor.

Also, the light triggered element 16 may be a photothyristor or bidirectional photothyristor having a zero-cross function, in which case a load turn-on/off control is enabled. In this case, there is a merit of higher noise-withstanding level, as compared with non zero-cross cases.

Further, the solid-state relay 30, which is composed of the first light emitting element 10 and the light triggered element 16, may be replaced with a solid-state relay formed of a gate trigger-type thyristor or bidirectional thyristor.

### Fourth Embodiment

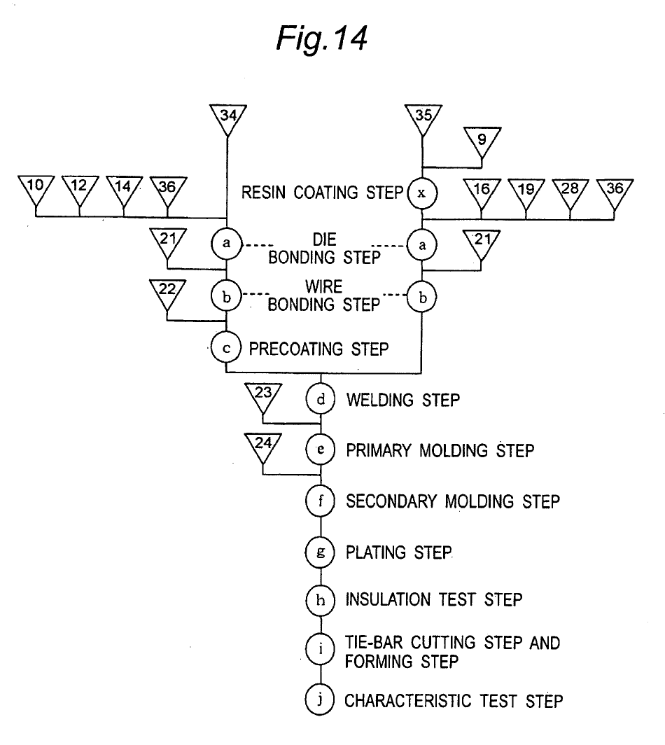

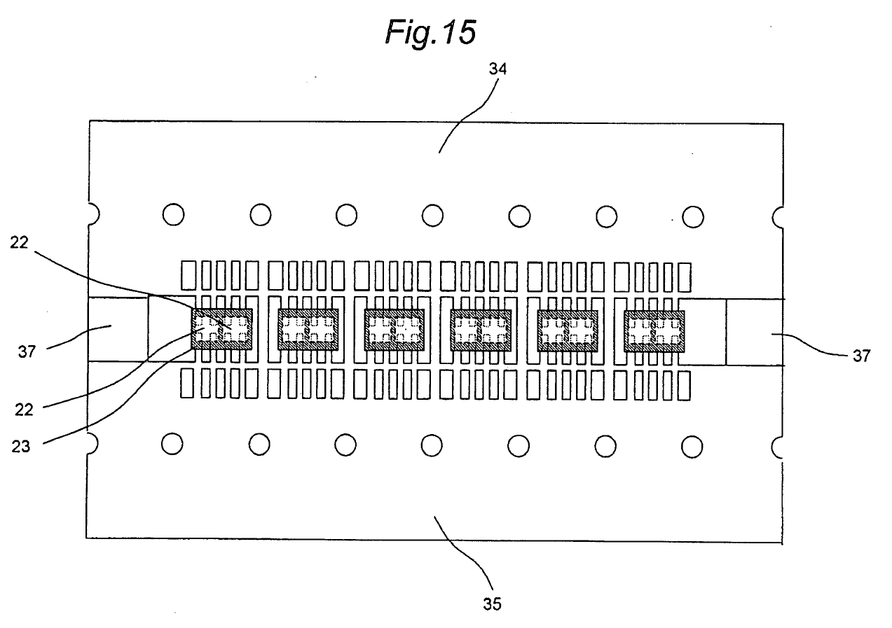

Next, a manufacturing method of the semiconductor device according to a fourth embodiment of the invention is described. FIG. 14 shows a flowchart of manufacturing process for the semiconductor device in the fourth embodiment, and FIG. 15 shows a plan view of the semiconductor device before its insulation cutting. In this fourth embodiment, not only the manufacturing method for the semiconductor device of the first embodiment is described, but also manufacturing methods for the semiconductor devices of the second and third embodiments are also described.

In a secondary-side lead frame 35 shown in FIG. 15, insulative resin 9 is formed at a place where the light triggered element 16 is to be set (resin coating step ‘x’). In the third embodiment, the insulative resin 9 is formed also at a place where the temperature sensor 28 is to be set.

Next, the first light emitting element 10, the second light emitting element 12 and the third light emitting element 14 are die-bonded to connecting portions of a primary-side lead frame 34 with silver paste 36 (die bonding step ‘a’), and interconnections are wrought with wires 21 (wire bonding step ‘b’).

Next, all of the first, second, third light emitting elements 10, 12, 14 are precoated with precoat resin 22 formed of silicon resin (precoating step ‘c’).

Also, the die bonding step ‘a’ and the wire bonding step ‘b’ are applied to specified places in the secondary-side lead frame 35, where the light triggered element 16 and the phototransistor 19 are mounted. In this process, for the semiconductor devices of the second embodiment and the third embodiment, the temperature sensor 28 is also mounted in the die bonding step ‘a’ and the wire bonding step ‘b’.

Then, the primary-side lead frame 34 and the secondary-side lead frame 35 are welded together at welding joint portions 37 (shown in FIG. 15) provided at their both end portions (welding step ‘d’).

Next, primary molding is carried out with the translucent resin 23 (primary molding step ‘e’).

Further, secondary molding is carried out with the light shielding resin 24 (secondary molding step ‘f’).

The light shielding wall 25 in FIGS. 2, 6 and 9 is formed during the secondary molding step.

Thereafter, outwardly exposed portions of the leads are plated (plating step ‘g’) and subjected to an insulation withstand voltage test (insulation test step ‘h’). In addition, in the modification of the third embodiment shown in FIG. 13, the heat sink plate 38 is attached during the plating step ‘g’.

Next, the leads are cut and, in some cases, may be folded for an easier use of the leads (tie-bar cutting step and forming step ‘i’).

Further, an electrical test is carried out (characteristic test step ‘j’), followed by execution of exterior plating, forming and the like, by which the semiconductor device is completed.

In this semiconductor device manufacturing method, the light triggered element 16 and the temperature sensor 28 are mounted on the same lead via the insulative resin 9. As a result of this, the temperature of the light triggered element 16 can be easily detected by the temperature sensor 28 while the light triggered element 16 and the temperature sensor 28 are electrically insulated from each other.

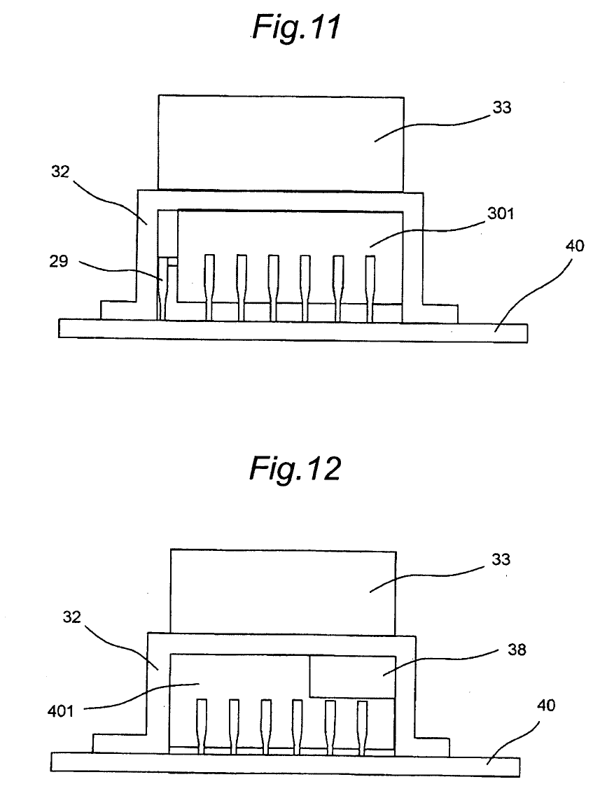

According to this invention, as shown in FIGS. 11 and 12, an LED light source 33 as an example of the load may be combined with the second and third embodiments of the invention to make up an integrated module, which allows a miniaturization as an illuminating device to be achieved. As the LED light source 33 involves large amounts of heat generation in its use, the function of overheat protection control is also effective.

As shown in FIG. 11, a semiconductor device 301 is mounted on a board 40 and a heat sink plate 32 formed of metal, ceramic or the like is placed so as to cover the semiconductor device 301. Then, the LED light source 33 is mounted on the heat sink plate 32. The eleventh lead 29 of the semiconductor device 301 is set in contact with the heat sink plate 32.

With the structure in which the heat sink plate 32 is provided below the LED light source 33 while the heat sink plate 32 and the eleventh lead 29 are set in contact with each other as shown above, the temperature of the LED light source 33 can be sensed by the temperature sensor 28 via the eleventh lead 29.

Also, as shown in FIG. 12, a semiconductor device 401 is mounted on the board 40 and the heat sink plate 32 formed of metal, ceramic or the like is placed so as to cover the semiconductor device 401. Then, the LED light source 33 is mounted on the heat sink plate 32. The heat sink plate 38 of the semiconductor device 401 is set in contact with the heat sink plate 32.

With the structure in which the heat sink plate 32 and the heat sink plate 38 of the semiconductor device are set in contact with each other as shown above, a more accurate temperature sensing can be achieved by heat conduction of the heat sink plate 38. Feeding back the sensed temperature to the pulse generation section 202a as in the power control device shown in FIG. 5 makes it possible to implement phase control to lower the output so that the temperature of the LED illuminating device does not go beyond a maximum rated temperature, thus overheat protection control being achievable. Also, the paste material for connections of the temperature sensor 28 and the connecting portions of the lead 26 and the lead 27 may be the same as the material used for the die bonding of the other leads and the light triggered element 16 or the phototransistor 19. Thus, the manufacturing cost can be reduced.

Further, by providing a module in which the semiconductor device or power control device and the LED light source are integrated together, a miniaturization as an illuminating device can be implemented. Integration with the power control device makes it possible also to implement the overheat protection control on the LED light source involving large amounts of heat generation in its use.

The temperature sensor used in illumination or other purposes, if provided by using a thermistor, becomes easier to make up. For sensibility of slight differences in temperature, it is desirable to use a thermistor having a negative temperature coefficient of small absolute value in real temperature level.

With the use of a thermistor for the temperature sensor, the temperature sensor can be placed in a small region within the package, allowing a miniaturization of the device to be achieved.

Whereas embodiments of the semiconductor device according to the present invention have been described above, the invention may also be applied to packages of the plane mount type (e.g., T0220 type) in which light emitting elements and light receiving elements are placed on an identical plane.

The semiconductor device of the invention may also be applied to electronic equipment such as lighting equipment and household electrical appliances, allowing the effective use of mounting spaces to be achieved.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor device for use in power control devices for controlling AC power fed from an AC power supply to a load, comprising:
a solid-state relay having: a first light emitting element to which a control signal for control of the AC power is inputted; a light triggered element for, upon reception of light from the first light emitting element, turning on and off an AC voltage applied from the AC power supply to the load; and a first resin sealing portion for sealing the first light emitting element and the light triggered element with translucent resin;
a bidirectional input-type photocoupler having: second, third light emitting elements which are connected in parallel in mutually opposite directions and to which a signal representing the AC voltage is inputted; a phototransistor for, upon reception of light from the second, third light emitting elements, outputting a signal representing a zero cross of the AC voltage; and a second resin sealing portion for sealing the second, third light emitting elements and the phototransistor with translucent resin; and
a light shielding wall for light-shielding the solid-state relay and the bidirectional input-type photocoupler from each other, wherein
in a state that the solid-state relay and the bidirectional input-type photocoupler are light-shielded from each other by the light shielding wall, the solid-state relay and the bidirectional input-type photocoupler are integrated into one package.

2. The semiconductor device as claimed in claim 1, wherein
the first, second, third light emitting elements are placed at connecting portions of a plurality of leads in which the connecting portions are arrayed along one identical plane.

3. The semiconductor device as claimed in claim 1, wherein
the light triggered element and the phototransistor are fixed to the connecting portions of the leads with high heat conductivity paste or solder, and
the light triggered element and the phototransistor are electrically insulated from each other.

4. The semiconductor device as claimed in claim 1, further comprising
a temperature sensor which is placed in the one identical package of the solid-state relay and the bidirectional input-type photocoupler, and which is fixed to the connecting portions of the leads with high heat conductivity paste or solder.

5. The semiconductor device as claimed in claim 4, wherein
the temperature sensor detects a junction temperature of the light triggered element or a package temperature.

6. The semiconductor device as claimed in claim 5, wherein
the temperature sensor and the light triggered element are placed on one lead, and
the lead on which the temperature sensor and the light triggered element are placed is led outside.

7. The semiconductor device as claimed in claim 5, wherein
the temperature sensor and the light triggered element are placed on one lead, the semiconductor device further comprising
a heat sink plate which is attached to the lead on which the temperature sensor and the light triggered element are placed.

8. The semiconductor device as claimed in claim 4, wherein
the temperature sensor is a thermistor.

9. The semiconductor device as claimed in claim 1, wherein
the light triggered element is a photothyristor or a bidirectional photothyristor, or has a structure that a gate of a triac is connected to an output terminal of a photothyristor or a bidirectional photothyristor.

10. The semiconductor device as claimed in claim 1, wherein
the light triggered element is a photothyristor or bidirectional photothyristor having a zero-cross function.

11. A method for manufacturing a semiconductor device for use in power control devices for controlling AC power fed from an AC power supply to a load, the semiconductor device comprising:
a solid-state relay having: a first light emitting element to which a control signal for control of the AC power is inputted; a light triggered element for, upon reception of light from the first light emitting element, turning on and off an AC voltage applied from the AC power supply to the load; and a first resin sealing portion for sealing the first light emitting element and the light triggered element with translucent resin;
a bidirectional input-type photocoupler having: second, third light emitting elements which are connected in parallel in mutually opposite directions and to which a signal representing the AC voltage is inputted; a phototransistor for, upon reception of light from the second, third light emitting elements, outputting a signal representing a zero cross of the AC voltage; and a second resin sealing portion for sealing the second, third light emitting elements and the phototransistor with translucent resin;
a light shielding wall for light-shielding the solid-state relay and the bidirectional input-type photocoupler from each other, and
a temperature sensor which is placed in one identical package of the solid-state relay and the bidirectional input-type photocoupler, and which is fixed to connecting portions of the leads with high heat conductivity paste or solder, wherein
in a state that the solid-state relay and the bidirectional input-type photocoupler are light-shielded from each other by the light shielding wall, the solid-state relay and the bidirectional input-type photocoupler are integrated into one package, the manufacturing method comprising the steps of:
applying insulative resin to regions on one lead at which the light triggered element and the temperature sensor are to be mounted, and
after the application of the insulative resin, mounting the light triggered element and the temperature sensor onto the one lead via the insulative resin.

12. A power control device comprising:
the semiconductor device as defined in claim 5;
a control section for, based on a signal representing a zero cross of the AC voltage outputted from the phototransistor of the bidirectional input-type photocoupler of the semiconductor device, outputting the control signal to the first light emitting element of the solid-state relay to turn on and off the light triggered element of the solid-state relay so that AC power fed from the AC power supply to the load is controlled, wherein
the control section performs overheat protection control for the semiconductor device based on a temperature detected by the temperature sensor of the semiconductor device.

13. Electronic equipment in which the semiconductor device as defined in claim 1 is mounted.

14. A module in which the semiconductor device as claimed in claim 1 or the power control device or the electronic equipment and an LED light source as the load are integrated together.
